(19) United States
(12) Patent Application Publication
(10) Pub. No.: US 2008/0213967 A1
(43) Pub. Date: Sep. 4, 2008

(54) TRENCH CAPACITOR AND METHOD FOR MANUFACTURING THE SAME

(76) Inventors: Yi-Nan Su, Tao-Yuan City (TW); Ta-Chuan Yeh, Tainan County (TW)

Correspondence Address: NORTH AMERICA INTELLECTUAL PROPERTY CORPORATION, P.O. BOX 506, MERRIFIELD, VA, 22116, US

(21) Appl. No.: 12/030,883

(22) Filed: Feb. 14, 2008

Related U.S. Application Data
(63) Continuation-in-part of application No. 11/162,489, filed on Sep. 12, 2005.

(51) Int. Cl. H01L 21/20; H01L 29/92

(52) U.S. Cl. 438/386; 257/532; 257/E21.008; 257/E29.342

(57) ABSTRACT

Method of manufacturing a trench capacitor includes providing a substrate having a memory array region and a logic region, performing a shallow trench isolation (STI) process for forming at least a STI in the substrate within each of the memory array regions and the logic regions, forming a patterned hard mask and the hard mask exposing a portion of the STI and a portion of the substrate surrounding the STI on the substrate, performing a first etching process to form first deep trenches through the patterned hard mask, performing a second etching process to form second deep trenches extending downwardly from the first deep trenches respectively, and forming a capacitor structure in each of the first deep trenches and the second deep trenches.

### CROSS REFERENCE TO RELATED APPLICATIONS

This is a continuation-in-part of U. S. patent application Ser. No. 11/162,489 filed Sep. 12, 2005.

### BACKGROUND OF THE INVENTION

1. Field of the Invention

The invention relates to a structure of a trench capacitor and method for manufacturing the same, and more particularly, to a method of manufacturing a trench capacitor in which the STI process is compatible with the logic processes, and in which the capacitive area is effectively increased.

2. Description of the Prior Art

As electronic products trend is heading towards increased miniaturization, DRAM devices need to have a higher integration and density. Trench capacitor DRAM devices are one such high density DRAM popularly used in the industry, and that which is formed in a deep trench capacitor in the semiconductor substrate for effectively decreasing the size of the memory unit and efficiently utilizing the chip area.

Please refer to FIGS. 1-2, which are schematic cross-sectional views the showing the shallow trench isolation (STI) regions between trench capacitors according to a conventional fabrication method. As shown in FIG. 1, a semiconductor chip 10 comprises a memory array region 14 and a logic region 16. As indicated, a plurality of trench capacitors 18 are formed in the silicon substrate 12 within the memory array region 14 of the semiconductor chip 10. Typically, each of the trench capacitors 18 is formed by etching using a hard mask 20 to form a deep trench opening (not shown) inside the silicon substrate 12; and then an electrode of the capacitor (not shown), a poly storage node 24, serving as the other electrode of the capacitor, and a node dielectric layer 22 at between the two electrodes, are formed inside the deep trench opening.

Referring to FIG. 2, then, an etching process is performed to etch the hard mask 20, the silicon substrate 12, a portion of the storage node 24, and the node dielectric layer 22 through a patterned bottom reflection coating (BARC) layer (not shown), thereby forming isolation trenches (not shown) inside the memory array region 14 and the logic region 16. Then, the isolation trenches are filled with gap fill dielectric materials, and are planarized. Thus, a plurality of shallow trench isolations (STIs) 38 are obtained.

However, there are several problems with the above-described conventional method because of the complexities of the trench capacitors 18 and the STI etching process: first, the thick hard mask 20 leads to poor critical dimension (CD) uniformity and larger iso/dense CD bias. Secondly, the STI trench recipe is difficult to setup because of the complex structures of the trench capacitor 18. Thirdly, the STI formation in the conventional method for making trench capacitor DRAM devices is not compatible with the logic processes.

Therefore, U.S. patent application Ser. No. 11/162,489 provides a method for manufacturing trench capacitors for solving the above-mentioned problems. Please refer to FIGS. 3-6 that are schematic diagrams of the method for manufacturing trench capacitor according to U.S. patent application Ser. No. 11/162,489. As shown in FIG. 3, the method provides a semiconductor chip 50 having a defined logic region 54 and a memory array region 56. A plurality of STI openings (not shown) are formed inside the memory array region 56 and the logic region 54. The STI openings are formed in the substrate 52 (such as silicon substrate), an oxide layer 58, and a silicon nitride layer 60 by using a mask (not shown). Then the STI opening are formed by being filled with an insulating material 66, e.g. silicon oxide, and are planarized. Thus, a plurality of STI regions 62, 64 are obtained respectively in the memory array region 56 and the logic region 54.

As shown FIG. 4, then, a patterned photoresist layer 70 and a hard mask 68 are formed on the silicon nitride layer 60 and the STI regions 62, 64 for defining a plurality of deep trenches. The material of the hard mask 68 often comprises silicon oxide or silicon nitride. The first problem encountered with the material is: when the hard mask 68 is comprised of silicon nitride and is thick enough to sustain the etching for forming the deep trench openings 72, the hard mask 68 may cause a substantial stress to the substrate 52, even to extent of rendering a serious damage. On the other hand, when the hard mask 68 is comprised of silicon oxide, another serious damage is resulted to the STI regions 62, 64 during the removal of the hard mask 68, because of the poor etching ratio existing between the hard mask 68 and the STI regions 62, 64, which are both made of silicon oxide.

Next, as shown in FIG. 5, an etching process is performed to etch the STI 62, the silicon nitride layer 60, the oxide layer 58, and the substrate 52 exposed by the photoresist layer 70 within the memory array region 56, and to form a plurality of deep trench openings 72. It is to be appreciated that the deep trench openings 72 are formed after the STI region 62 is formed.

Finally, as shown FIGS. 5-6, a plurality of trench capacitors 74 are formed inside the deep trench openings 72 by the following steps: First, a collar oxide layer 76 is formed on the sidewalls of the deep trench openings 72. The collar oxide layer 76 exposes the bottoms of the deep trenches openings 72. Then a conductive layer is formed inside the deep trench openings 72 to be a plurality of capacitor bottom electrodes 78, along the sidewall and in the bottom of each deep trench opening 72. Then, a capacitor dielectric layer 80 is formed in each deep trench opening 72. Finally, a conductive material (not shown), such as polysilicon, is filled into the deep trench openings 72, and a CMP process is performed to polish the conductive material up to the silicon nitride layer 60. Consequently, the capacitor top electrodes 82 are formed in the deep trench openings 72. In this conventional method, the capacitor dielectric layer 80 is an oxide/nitride/oxide layer; however, other single layer material or composite materials can also be adopted. It is noteworthy that a doped region such an n-band 82 is formed through a photoresist (not shown) as shown in FIG. 6. The purpose of the n-band 80 is to maintain the capacitor bottom electrode 78 at an uniform voltage, and to provide an electrical connection between the capacitor bottom electrode 78 and other doped regions such as an n-type n-well (not shown).

The conventional method has benefits of better critical dimension (CD) uniformity, less iso/dense CD bias, and the aforementioned method further provides an STI process that is compatible with logic processes to enhance quality and decrease the cost by fabricating the STI regions before the trench capacitor. However, should the depths of the deep trench openings 72 to be not controlled precisely during the etching process, the capacitor bottom electrode 78 may fail to contact the n-band 82, thus cutting off the electrical connection between the capacitor bottom electrode 78 and the other doped region.

More important, it is well known that the increase of the capacitive area is one approach to increase capacitance. In the trench capacitor case, the deep trench opening 72 leads to the larger capacitive area, and consequently, to larger capacitance. As shown in FIGS. 5-6, a deeper deep trench opening 72 is to mean that a deeper n-band 82, which has to be electrically connected to the capacitor bottom electrode 78, is needed. However, the depth of the n-band 82 is limited by the thickness of the photoresist serving as an implant mask, while the thickness of the photoresist adversely affects pattern density: a deeper n-band 82 requires a thicker photoresist, which may fail to form the high-density deep trench pattern due to having a higher aspect ratio. Simply speaking, the depth of the trench capacitor, the capacitive area, and the capacitance are limited by the depth of the n-band 82.

### SUMMARY OF THE INVENTION

It is therefore a primary objective of the claimed invention to provide a trench capacitor and method of manufacturing the same to solve the above-mentioned problem.

According to the claimed invention, a method of manufacturing a trench capacitor is provided. The method comprises steps of providing a substrate having a memory array region and a logic region defined thereon; performing a shallow trench isolation (STI) process for form at least a STI in the substrate within each of the memory array region and the logic region; forming a patterned hard mask and the patterned hard mask exposing a portion of the STI and a portion of the substrate surrounding the STI in the memory array region on the substrate; performing a first etching process to form a plurality of first deep trenches through the patterned hard mask; performing a second etching process to form a plurality of second deep trenches extending downwardly from the first deep trenches, respectively; and forming a capacitor structure in each of the first deep trenches and the second deep trenches.

According to the claimed invention, a trench capacitor is provided. The trench capacitor includes a substrate, an STI disposed in the substrate, a plurality of first deep trenches formed adjacent to the STI in the substrate, a doped band formed underneath the first deep trenches, a plurality of second deep trenches extending downwardly from the first deep trenches, and a plurality of capacitor structures respectively positioned in each of the first deep trenches and the second deep trenches.

According to the present invention, the first deep trenches are etched into a depth that is also a pre-determined position for the doped band, and the second deep trenches are formed downwardly from the first deep trenches. It is without a doubt that the second deep trenches would pass through the doped band; therefore, the capacitor bottom electrodes formed in the second deep trenches are assured to be electrically connected to the doped band, and the consideration of forming a deeper doped band is thus eliminated. Based on this assurance, the depth of the second deep trenches thereby has no limitations. Consequently, the capacitance of the trench capacitor is substantially improved, while the formation and the positioning of the doped band are not influenced at all.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are schematic cross-sectional views showing the fabrication of a plurality STI regions between trench capacitors according to a conventional method.

FIGS. 3-6 are schematic cross-sectional views showing the fabrication of the STI regions between trench capacitors according to U.S. patent application Ser. No. 11/162,489.

FIGS. 7-13 are schematic diagrams of a method for manufacturing trench capacitor according to an embodiment of the present invention.

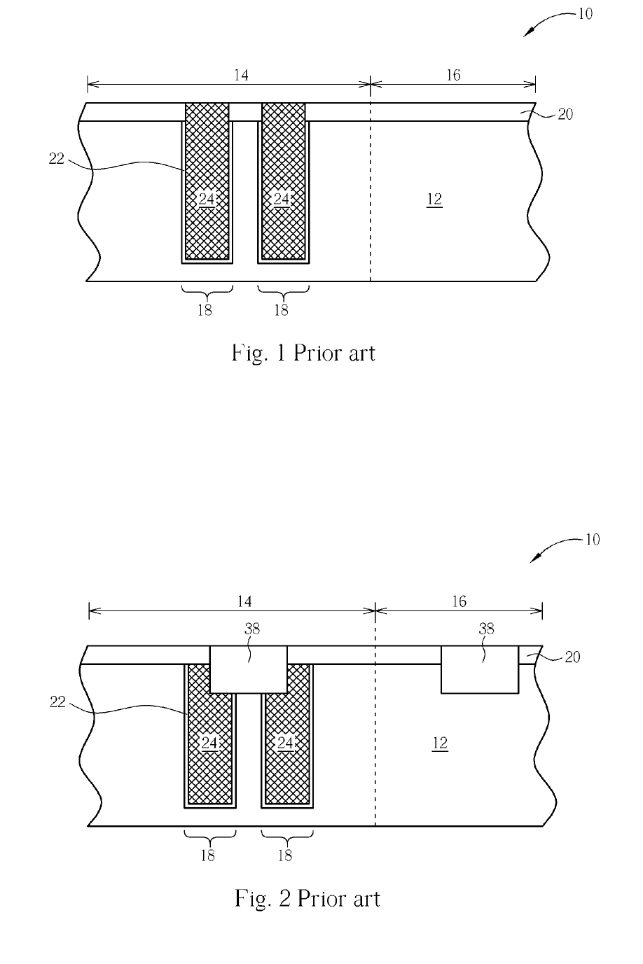

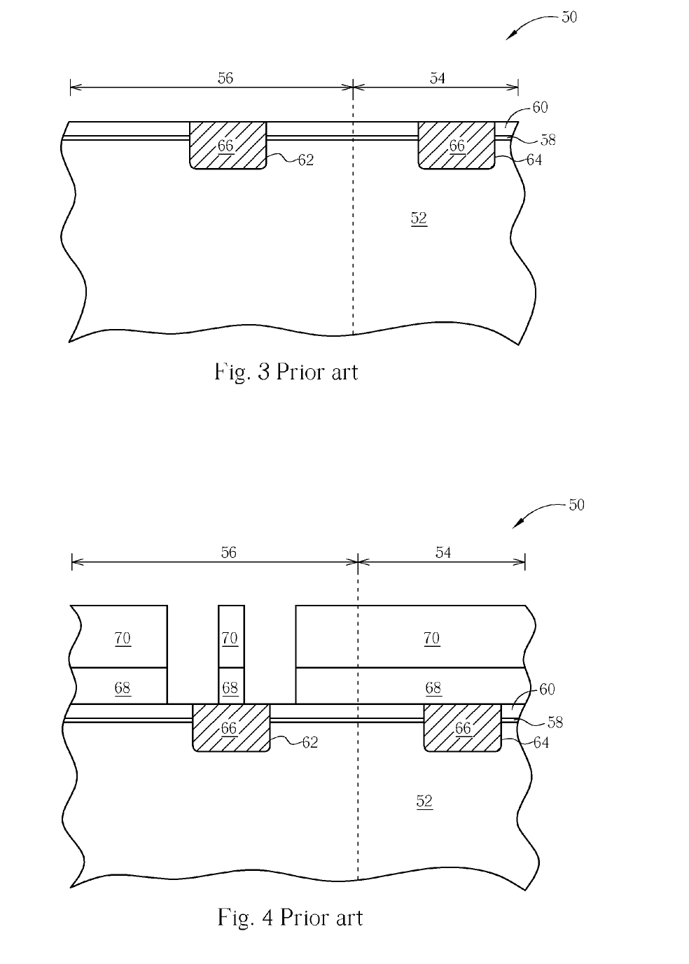

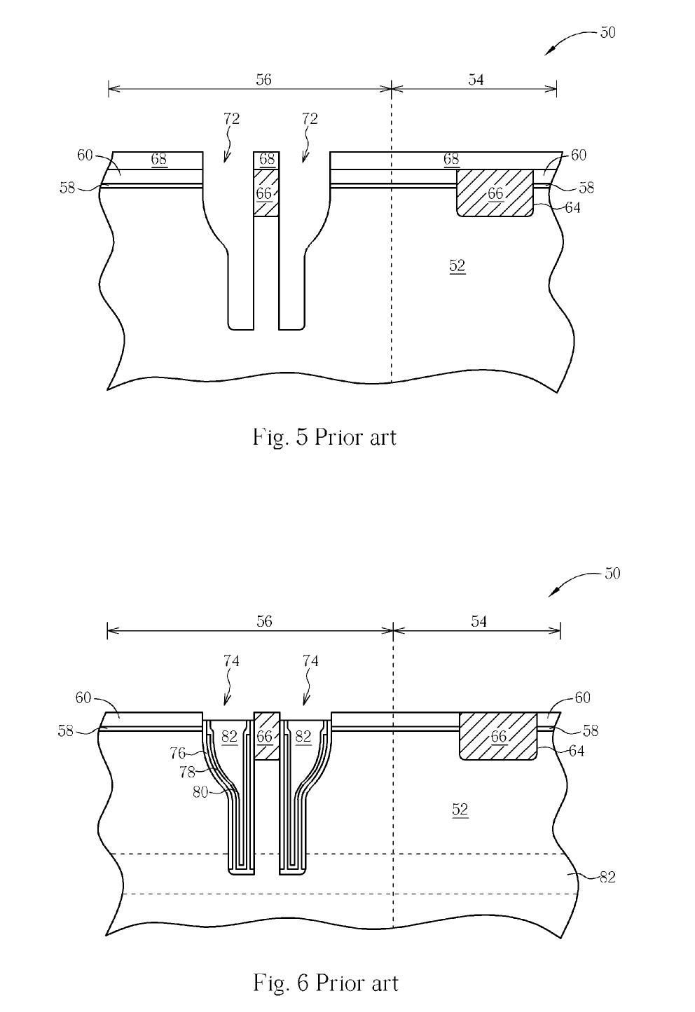

### DETAILED DESCRIPTION

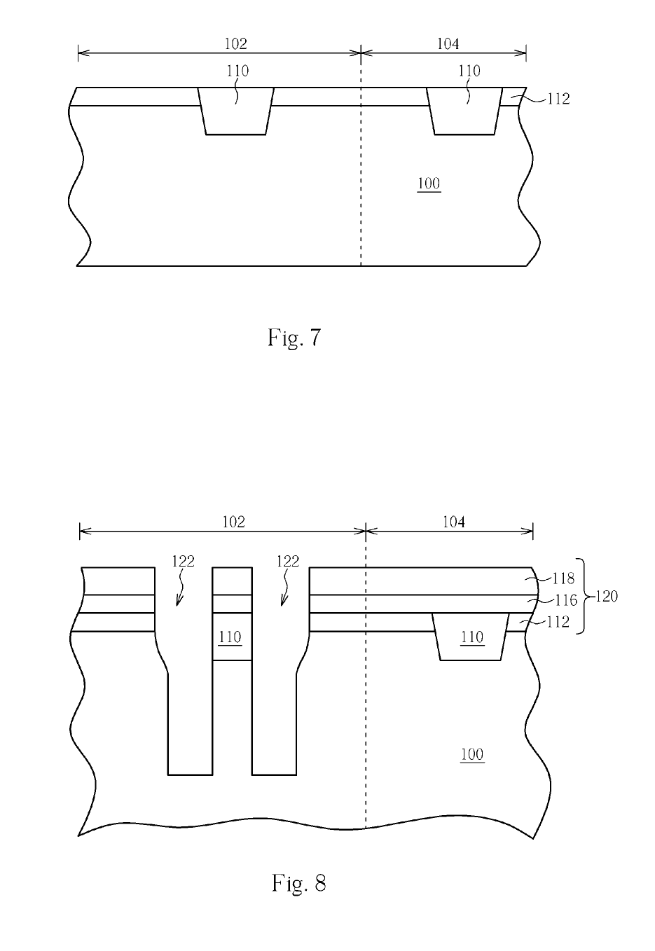

Please refer to FIGS. 7-13 that are schematic diagrams of a method for manufacturing trench capacitor according to an embodiment of the present invention. As shown in FIG. 7, the present invention provides a semiconductor substrate 100 having a memory array region 102 and a logic region 104 defined thereon. Next, a shallow trench isolation (STI) process is performed to form a plurality of STI 110 in the substrate 100 within the memory array region 102 and the logic region 104: firstly, a pad layer 112, made of silicon nitride (SiN), and a mask layer (not shown) are sequentially formed and patterned on the substrate 100; then an etching process is performed to form the STI openings (not shown) in the substrate 100 within the memory array region 102 and the logic region 104. The STI openings are filled with insulating materials, for example, silicon oxide, and planarized, thus the STIs 110 are obtained.

Please refer to FIG. 8, a hard mask 120 is formed on the substrate 100. The hard mask 120 is a bi-layered hard mask and is sequentially comprises a SiN layer 116, serving as a buffer layer, and a plasma enhanced silicon oxide (PEOX) layer 118. The SiN layer 116 comprises a thickness of 100-1500 angstroms. Then, the hard mask 120 is patterned to expose a portion of the STI 110 and a portion of substrate 100 surrounding the STI 110. In addition, a bottom anti-reflection (BARC) layer (not shown) can be formed on the hard mask 120 selectively.

Please still refer to FIG. 8. Next, a first etching process is performed to etch the STI 110, the pad layer 112, and the substrate 100 not covered by the patterned hard mask 120 within the memory array region 102, and to form a plurality of first deep trenches 122. It is noteworthy that the first deep trenches 122 are formed having a depth of about 1-1.5 micron. Each of the first deep trench 122 has a vertical sidewall in contact with the STI 110 and a curved sidewall which is not in contact with the STI 110.

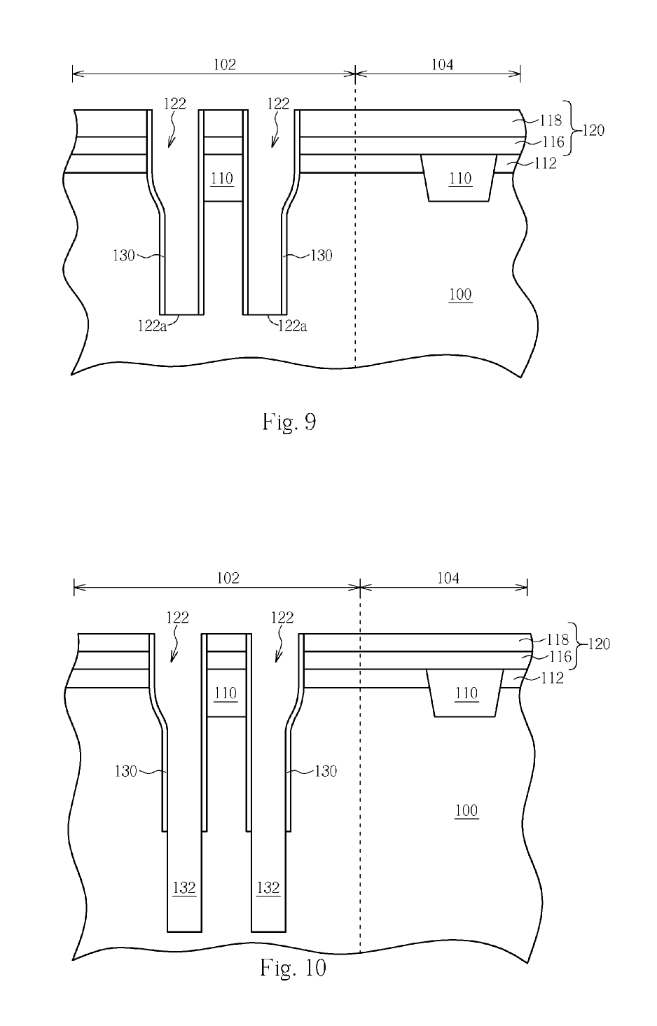

Please refer to FIG. 9. Then, a collar oxide layer 130, having a thickness of about 100-150 angstroms, is formed in the first deep trenches 122. After the collar oxide layer 130 is formed on the sidewalls and bottom surfaces of the first deep trenches 122, an etching process, such as an anisotropic dry etching process, is carried out to etch away a portion of the collar oxide layer 130 from a plurality bottom surfaces 122a of the first deep trenches 122, thereby exposing the bottom surfaces 122a of the first deep trenches 122.

As shown in FIG. 10, a second etching process is performed and a plurality of second deep trenches 132 extending downwardly from the first deep trenches 122 are formed.

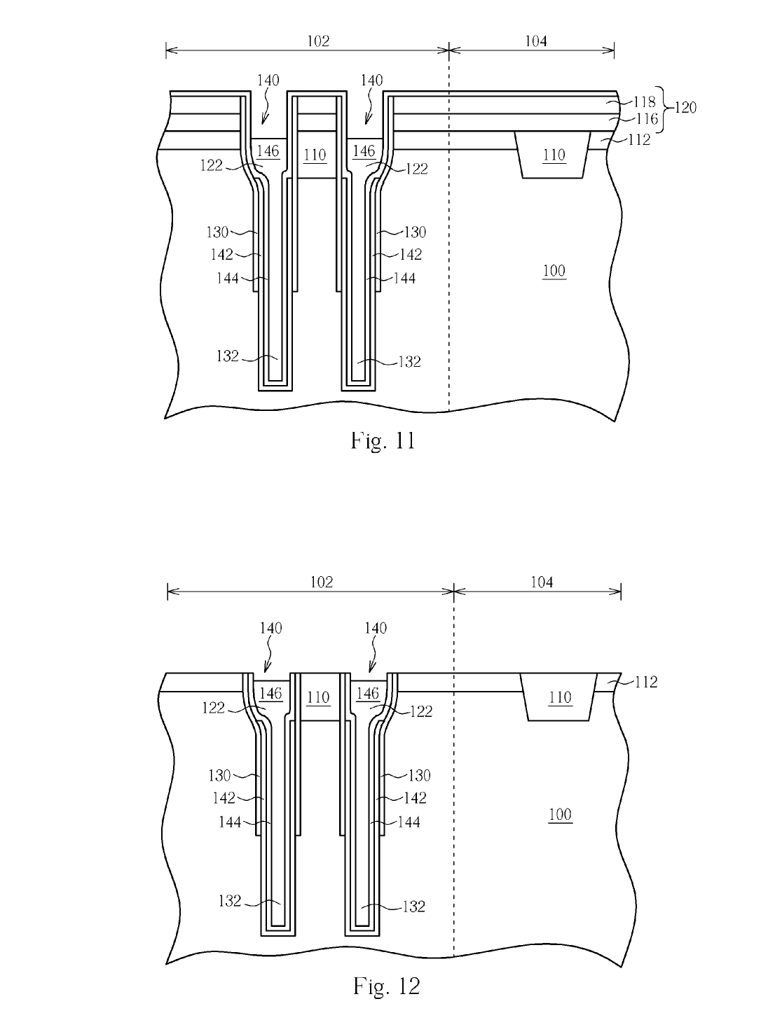

Please refer to FIG. 11. Next, a plurality of capacitor structures 140 are formed in the first deep trenches 122 and the second deep trenches 132 by the following steps: First, a conductive layer is formed in a portion of the first deep trenches 122 and the second deep trenches 132 to be a plurality of capacitor bottom electrodes 142 of the capacitor structures 140. Then, a capacitor dielectric layer 144 is formed in each of the first deep trenches 122 and the second deep trenches 132. In this embodiment, the capacitor dielectric layer 144 is an oxide/nitride/oxide layer; however, other single layer material or composite materials can also be adopted. Then, a conductive material is filled into the first deep trenches 122 and the second deep trenches 132 to form a plurality capacitor top electrodes 146 of the capacitor structures 140.

Please refer to FIG. 12. Then a CMP process is performed to polish the conductive material and to remove the hard mask 120 using the pad layer 116 serving as a stop layer.

It is noteworthy that since the hard mask 120 is a bi-layered hard mask, it is capable to sustain each etching processes without providing any stress to the substrate 100. More important, the buffer layer 116, which is made of SiN, and contact to the STI 110, including SiO, has left no damage to the profile or step height of the STI when being removed.

It is well known to those skilled in the art that after the STIs 110 are filled up with the insulating material, it is densified under a thermal condition. If the STI is formed after the trench capacitor is completed, such thermal condition would cause the polysilicon in the substrate to recrystallize, thus a stress adversely affecting quality of the capacitor dielectric layer 144 is consequently caused by the recrystallized polysilicon. Therefore, another nitridation process is needed before forming the capacitor top electrode 146. However, in the present invention, since the STIs 110 are formed before forming any elements of a trench capacitor, the aforementioned stress caused from the recrystallization would not influence qualities of the elements of the trench capacitor at all. Therefore, the aforementioned nitridation process can be deleted in the present invention.

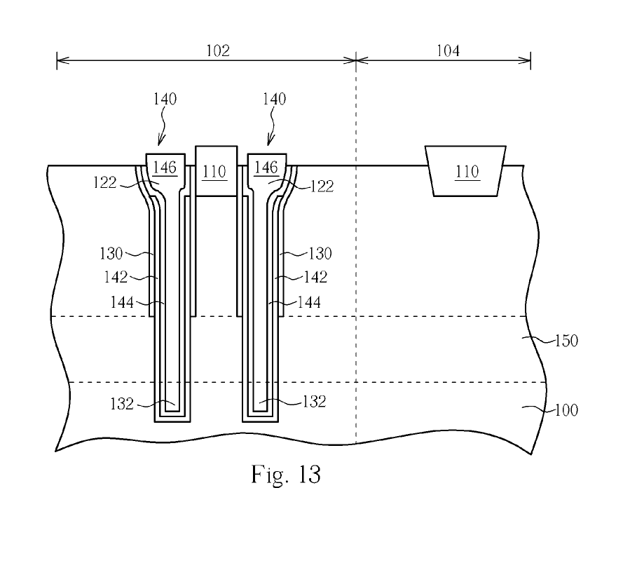

Please refer to FIG. 13. Then, the pad layer 112 is removed, and an implantation process is performed to form a doped band 150 after the capacitor structures 140 are formed. It is noteworthy that even though the doped band 150 is either an n-type band or a p-type band, whose conductivity type may be different from the deep n-well (not shown) in the logic region, the deep n-well and the doped band 150 can be formed using a same photomask in the photolithography process. The doped band 150 is formed in a depth of about 1-1.5 microns.

Please refer to FIG. 13 again. According to the embodiment of the present invention, a trench capacitor is provided. The trench capacitor comprises a substrate 100, an STI 110 disposed in the substrate 100, a plurality of first deep trenches 122 formed adjacent to the STI 110 in the substrate 100. The first deep trenches 122 are formed atop and in contact with a doped band 150. The trench capacitor also comprises a plurality of second deep trenches 132 extending downwardly from the first deep trenches 122. The second deep trenches 132 are formed extending through the doped band 150. And the trench capacitors further include a plurality of capacitor structures 140 respectively positioned in each of the first deep trenches 122 and second deep trenches 132.

The capacitor structure 140 further comprises a capacitor bottom electrode 142, a capacitor dielectric layer 144, and a capacitor top electrode 146 in each of the first deep trenches 122 and the second deep trenches 132. The capacitor dielectric layer 144 comprises an oxide/nitride/oxide layer.

As shown in FIG. 13, each of the first deep trenches 122 has a vertical sidewall in contact with the STI 110 and a curved sidewall not in contact with the STI 110. And the capacitor structure 140 of the trench capacitor further comprises a collar oxide layer 130 formed on the sidewalls of the first deep trenches 122. As seen in FIG. 13, the doped band 150 is formed underneath the collar oxide layer 130; and the collar oxide layer 130 can be formed to be in contact with the doped band 150. The doped band 150 can be an n-type band or a p-type band.

According to the embodiment of the present invention, the first deep trenches 122 are etched into a depth that is also at a pre-determined position for the doped band 150, and the second deep trenches 132 are etched downwardly from the first deep trenches 122. It is without doubt that the second deep trenches 132 would extend through the doped band 150; therefore, the capacitor bottom electrodes 142 formed in the second deep trenches 122 are assured to be electrically connected to the doped band 150. Based on this assurance, the depth of the second deep trenches 132 does not have any size limitations; consequently, the capacitance of the trench capacitor is substantially improved. In addition, the consideration of having to form deeper doped band 150 is also to be eliminated; and macro size is reduced.

Summarily, by performing a two-staged etching process provided by the embodiment of the present invention, the trench capacitor is achieved having a deep trench without limitations to its depth, and without the consideration of having to form deeper doped band. Therefore, the capacitance of the trench capacitor is substantially improved, while the formation and the position of the doped band are not affected at all.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a trench capacitor comprising:
providing a substrate having a memory array region and a logic region defined thereon;
performing a shallow trench isolation (STI) process for forming at least a STI in the substrate within each of the memory array region and the logic region;
forming a patterned hard mask and the patterned hard mask exposing a portion of the STI and a portion of the substrate surrounding the STI in the memory array region;
performing a first etching process to form a plurality of first deep trenches through the patterned hard mask;
performing a second etching process to form a plurality of second deep trenches extending downwardly from the first deep trenches, respectively; and
forming a capacitor structure in each of the first deep trenches and the second deep trenches.

2. The method of claim 1 further comprising forming a pad layer before performing the STI process.

3. The method of claim 1 wherein the hard mask is a bi-layered hard mask.

4. The method of claim 3, wherein the bi-layered hard mask sequentially comprises a silicon nitride (SiN) layer serving as a buffer layer and a plasma enhanced oxide (PEOX) layer.

5. The method of claim 4, wherein the SiN layer comprises a thickness of 100 to 1500 angstroms.

6. The method of claim 1, wherein the first deep trenches are formed having a depth of about 1 to 1.5 micron.

7. The method of claim 1 further comprising forming a doped band in the substrate after forming the capacitor structure.

8. The method of claim 7, wherein the doped band is formed in a depth of about 1 to 1.5 micron.

9. The method of claim 7, wherein the first deep trenches are formed atop the doped band.

10. The method of claim 9, wherein the first deep trenches are formed in contact with the doped band.

11. The method of claim 7, wherein the second deep trenches are formed extending through the doped band.

12. The method of claim 7, wherein the doped band is an n-type band or a p-type band.

13. The method of claim 1 further comprising forming a collar oxide layer on the sidewalls of the first deep trenches after the first etching process.

14. The method of claim 13, wherein the second etching process is performed after forming the collar oxide layer.

15. The method of claim 1, wherein the capacitor structure comprises a capacitor bottom electrode, a capacitor dielectric layer, and a capacitor top electrode.

16. A trench capacitor comprising:
a substrate;
an STI disposed in the substrate;
a plurality of first deep trenches formed adjacent to the STI in the substrate;
a doped band formed underneath the first deep trenches;
a plurality of second deep trenches extending downwardly from the first deep trench; and
a plurality of capacitor structures respectively positioned in each of the first deep trenches and the second deep trenches.

17. The trench capacitor of claim 16, wherein each of the first deep trenches has a vertical sidewall in contact with the STI, a curved sidewall not in contact with the STI.

18. The trench capacitor of claim 16, wherein the first deep trenches are formed in contact with the doped band.

19. The trench capacitor of claim 16, wherein the second deep trenches are formed extending through the doped band.

20. The trench capacitor of claim 16, wherein the doped band is an n-type band or a p-type band.

21. The trench capacitor of claim 16, wherein the capacitor structure further comprises a collar oxide layer formed on the sidewalls of the first deep trenches.

22. The trench capacitor of claim 21, wherein the doped band is formed underneath the collar oxide layer.

23. The trench capacitor of claim 22, wherein the collar oxide layer is formed in contact with the doped band.

24. The trench capacitor of claim 16, wherein the capacitor structure further comprises a capacitor bottom electrode, a capacitor dielectric layer, and a capacitor top electrode in each of the first deep trenches and the second deep trenches.

25. The trench capacitor of claim 24, wherein the capacitor dielectric layer comprises an oxide/nitride/oxide layer.
